(19) United States
(12) Patent Application Publication
(10) Pub. No.: US 2019/0348560 A1
(43) Pub. Date: Nov. 14, 2019

(54) METHOD FOR PRODUCING REAR SURFACE CONTACT SOLAR CELLS FROM CRYSTALLINE SILICON

(71) Applicant: EnBW Energie Baden-Wuerttemberg AG, Karlsruhe (DE)

(72) Inventors: Morris Dahlinger, Stuttgart (DE); Kai Carstens, Stuttgart (DE); Juergen H. Werner, Stuttgart (DE); Juergen Koehler, Waiblingen (DE); Sebastian Eisele, Glatten (DE); Tobias Roeder, Muenchen (DE); Erik Hoffmann, Stuttgart (DE)

(73) Assignee: EnBW Energie Baden-Wuerttemberg AG, Karlsruhe (DE)

(21) Appl. No.: 16/096,313

(22) PCT Filed: Apr. 12, 2017
(86) PCT No.: PCT/EP2017/058746

§ 371 Date: Oct. 25, 2018

(30) Foreign Application Priority Data
Apr. 27, 2016 (DE) 10 2016 107 802.6

(51) Int. Cl. H01L 31/068; H01L 31/0216; H01L 31/0368; H01L 31/02; H01L 31/18

(52) U.S. Cl. CPC H01L 31/0682; H01L 31/02168; H01L 31/1868; H01L 31/0201; H01L 31/03682

(57) ABSTRACT

A back surface contact solar cell has a wafer with an anti-reflection layer on the front surface, with an emitter and a back surface field on the back surface, and with contacts, produced using laser ablation, on the back surface, wherein the pitch is at most 800 micrometers. Furthermore provided is a method for producing such a solar cell.

### BACKGROUND OF THE INVENTION

The invention relates to a method for producing back surface contact solar cells from crystalline silicon.

Known production methods use furnace diffusion for producing n-doped and p-doped regions and for contacting vapor-deposited metals. Masking steps are required both for the structured manufacture of the doped regions required in back surface contact solar cells and for metallization. Since the silicon wafer in the diffusion furnace has the same temperature every-where, diffusion occurs uniformly on the entire surface. For each of the diffusions, producing differently doped strips or point structures for the n and p regions on the back surface of the solar cell therefore requires either masking, which locally inhibits inward diffusion of the dopant atoms, or a local etching step following the diffusion in order to remove the region not to be diffused. In both cases, the application of a diffusion-inhibiting masking layer or an etch-resistant protective layer is required, as is its high-resolving structuring. Since both a boron diffusion and a phosphorus diffusion must take place locally, these steps are required prior to the furnace diffusion taking place and must also be accomplished very precisely relative to one another. In addition, opening a back surface passivation layer for contacting the solar cell requires great precision, so that a lithography step is required. Furthermore, applying the metal contacts requires at least one lithography step. If two different metals are used, two lithography steps are needed.

For the reasons presented above, producing back surface contact solar cells by means of masking using lithography is not economical.

According to WO 2007/081510 A2, a back surface contact solar cell is produced from crystalline silicon in that precursor layers for subsequent furnace diffusion are printed locally by means of screen printing or ink-jet printing.

Such manufacture leads to imprecise matching of the doped regions and thus to sub-optimal efficiency.

Known in principle from DE 10 2004 036 220 A1 is producing, by means of laser doping, doped regions on solid bodies with a high degree of freedom from defects. First, a medium containing a dopant is brought into contact with a surface of the solid body. One region of the solid body lying below the surface that has been brought into contact with the medium is then melted for a short time by irradiation with laser pulses, so that the dopant diffuses into the melted region and recrystallizes free of defects while the melted region cools.

In principle, masking steps and lithography steps for doping using furnace diffusion may be avoided with such a method. The problem of simple and cost-effective contacting on the back surface of the solar cell remains.

Using a laser doping method to produce the doped regions is known from WO 2015/071217 A1. Contact surfaces on the back surface of the solar cell are exposed by means of laser ablation and are subsequently contacted by means of screen printing (see also M. Dahlinger, et al., “Laser-Doped Back-Contact Solar Cells,” IEEE Journal of Photovoltaics, Vol. 5, No. 3, May 2015, pp. 812-818, and M. Dahlinger, et al., “Laser Doped Screen-printed Back Contact Solar Cells Exceeding 21% Efficiency,” Energy Procedia, Vol. 55, September 2014, pp. 410-415).

Although screen printing is a cost-effective and proven method, it is not possible to attain great precision by means of screen printing, so that efficiency is limited. Furthermore, during screen printing the recombination of charge carriers is greater than, for example, using PVD (physical vapor deposition) deposited contacts.

Known from WO 2006/042698 A1, for contacting on a back surface contact solar cell, is first producing a metal layer on the back surface and then depositing an etching barrier layer, then selectively removing said etching barrier layer by means of a laser, and finally, attaining electrical separation between the different polarities using an etching step.

Fundamentally, however, even greater efficiency is desired.

According to WO 2015/047952 A1, a metal foil is applied for contacting. The foil is selectively welded by a laser and separated between the different polarities.

Such a method is very time consuming and expensive.

According to P. Verlinden et al., “High Efficiency Large Area Back Contact Concentrator Solar Cells with a Multilevel Interconnection,” International Journal of Solar Energy, 1988, Vol. 6, p. 347-366, producing contacting in back surface contact solar cells using an anodization method is known. The method is very complex due to various steps, including different lithography steps.

Finally, known from US 2016/0020343 A1 is transferring, by means of a laser transfer process, doping material or electrically conductive material, for instance to produce a finger structure for contacting.

Transferring using laser transfer is a somewhat complex process. In addition, greater efficiency is desired. Furthermore, laser transfer is generally limited to seed layers, that is, thin layers of a few 10s of nanometers thickness. These are not adequate as metallization for transporting current and as a rule must subsequently be made thicker, which requires an additional method step.

### SUMMARY OF THE INVENTION

Given this background, the underlying object of the invention is to provide a method for producing back surface contact solar cells from crystalline silicon, which method permits the simplest and least expensive production possible with high quality and the greatest possible efficiency.

This object is attained using a method for producing back surface contact solar cells from crystalline having the following steps:
(a) Doping, preferably by means of laser doping, for producing an n-doped or p-doped region;
(b) Exposing contact surfaces on the back surface of the solar cell, preferably by means of laser ablation;
(c) Applying a metal layer to a back surface of the solar cell; and,
(d) Structuring the metal layer by means of laser ablation for producing metal contacts, wherein the pitch is at most 800 micrometers.

The entire object of the invention is attained in this manner.

Since contacts are produced on the back surface of the solar cell using a laser ablation step according to (d), due to the great precision it is possible to obtain a small pitch that is at most 800 micrometers, preferably at most 500 micrometers, more preferably at most 100 micrometers, particularly preferably at most 60 micrometers. For example, the pitch may be about 50 micrometers.

According to the invention it has been found that efficiency increases as pitch decreases.

To permit the smallest possible pitch, the other steps during the production of the solar cells, such as the production of the doped regions and the exposure of contact surfaces, should, where possible, avoid lithography and masking steps and should avoid print techniques in order to provide the greatest possible precision overall. Laser technology is preferably used for each of these.

The pitch has a lower limit, depending on the precision when calibrating the laser used. A lower limit is a pitch of about 5 micrometers.

It is understood that the term “solar cell” is to be construed in its broadest sense. It also includes special forms, such as photo cells.

In another embodiment of the invention, after step (c), first an etch-resistant layer is applied that is selectively removed in step (d), and wherein the metal contacts, which are electrically separated from one another, are created using a subsequent etching step.

In this way short circuits between adjacent contacts are prevented without there being a risk of damage due to the laser penetrating too deep during ablation.

In one alternative embodiment of the inventive method, in step (c) an aluminum layer is applied, then a layer resistant to anodization is applied that in the subsequent step (d) is selectively ablated by means of laser and then is completely anodized in the ablated regions.

In this way, instead of complete removal of the aluminum remaining between adjacent polarities, complete conversion to aluminum oxide is attained, which likewise reliably prevents short circuits.

The remaining flat surface area results in a certain advantage.

In an additional refinement of the invention, the metal contacts are connected using bus-bars that comprise strips of metal foil that are contacted by means of laser welding through at least one interposing dielectric layer.

According to a first embodiment of the invention, strips of anodized aluminum foil are used to produce the bus-bars. The laser welding process occurs through the insulating layer for each polarity.

Naturally a different dielectric layer or a layer stack may be used on the foil strips or on the back surface of the wafer for insulation.

A laser doping step is preferably used for producing a p-type emitter and/or for producing an n back surface field (BSF) on the back surface of the solar cell.

To this end, preferably a precursor layer that contains a dopant, in particular boron, aluminum, or gallium, is preferably deposited on the back surface of the solar cell and a p-type emitter is created using local irradiation by means of a pulsed laser.

Alternatively, the p-type emitter may be created locally using ion implantation with a dopant, in particular boron, aluminum, or gallium.

In this way the emitter may be created with great precision and without masking or lithography steps.

According to a further embodiment of the invention, during the emitter doping by means of laser irradiation, greater doping is created using beam forming or by using another independently focused laser beam locally under the emitter contact surfaces. In the beam forming, it is critical that the pulse energy density is increased locally in the area of the contacts in order to obtain higher doping there. Corresponding beam forming may occur, e.g., using a diffractive optical element.

This makes possible particularly low-loss contacting in a simple manner.

A pulsed laser is preferably used for the laser doping, preferably having a pulse duration of 30 nanoseconds to 500 nanoseconds, further preferably having a wavelength of 500 to 600 nanometers, further preferably having a pulse repetition rate of 1 kHz to 2 MHz, further preferably having a pulse energy density of 1 J/cm² to 5 J/cm².

Using such a laser results in optimal matching to doping. The silicon surface and the precursor layer may be heated locally in this manner until the doping process may be performed locally to the desired depth in the briefest period of time, wherein at the same time excess doping may be prevented. Using a local variation in the pulse energy density, the doping may be adjusted optimally simultaneously in the contact areas and in the areas of the emitter that are not contacted.

The laser beam is preferably formed on a rectangular region X·Y by means of an optical element, and laser and substrate are moved incrementally relative to one another by an interval L in order to dope predefined surfaces.

In this way precise doping may be produced in rectangular or linear regions.

In this case, the width X is preferably 0.02 to 2 millimeters, while the length Y is preferably between 5 micrometers and 500 micrometers.

The interval L, by which the substrate and the laser are moved incrementally relative to one another, is preferably between 0.1·Y and Y. The entire desired surface area of a strip or point is doped by repeatedly irradiating and moving the silicon wafer, or by moving the laser beam formed on the surface in the Y direction, by the interval L.

In one advantageous refinement of the invention, for creating an n back surface field (B SF) on the back surface of the solar cell, first a phosphorus silicate glass layer (PSG) is deposited as a precursor on the substrate and is then irradiated by means of a laser to produce n-doping. The deposition of the PSG layer occurs simultaneously with front surface doping (front surface field, FSF) of the wafer in a high temperature diffusion furnace. The creation of an FSF permits improved passivation of the front surface of the solar cells.

After the laser doping, the phosphorus silicate glass layer is preferably removed using etching and then at least part of the phosphorus-doped layer on the back surface of the substrate is etched back.

Depending on the depth and phosphorus concentration, the etching back occurs on both sides of the silicon wafer or only on the back surface. The goal of the etching back step is to reduce the phosphorus present in the boron emitter regions. The phosphorus surface concentration in the emitter region may be adjusted by the etching back step such that, following a subsequent thermal oxidation, the phosphorus surface concentration is at least five times less than the boron surface concentration.

The phosphorus concentration on the front surface must be reduced if the latter is too highly doped with phosphorus. The goal here is a surface phosphorus concentration of about 1·10¹⁸ cm⁻³ to 1·10²⁰ cm⁻³ following a subsequent thermal oxidation step for optimal front surface passivation using the FSF produced in this manner. Additionally, the silicon wafer undergoes chemical cleaning due to the etching back.

After the laser doping of the BSF layer or after the partial etching back step, thermal oxidation is performed in the range of 700° C. to 1100° C., preferably 800° C. to 1050° C.

In this so-called drive-in step, silicon dioxide grows as surface passivation. Furthermore, due to the high temperatures, the dopant atoms diffuse further into the silicon wafer. Because of this, the surface concentration of the doping drops in both the solar cell emitter and in the BSF and FSF.

In a further preferred embodiment of the invention, an anti-reflection layer is deposited on the front surface, preferably a silicon nitride layer deposited by means of PECVD.

A stack layer made of low-silicon and high-silicon silicon oxide or silicon nitride is preferably deposited on the back surface of the solar cell, preferably by means of PECVD.

The low-silicon layer preferably has a low refractive index (n<1.7) and a thickness between 70 nanometers and 300 nanometers, while the subsequent high-silicon layer is preferably a layer having a high refractive index (n>2.7) and a thickness between 10 nanometers and 100 nanometers. Both layers may be deposited one after the other in the same process step in the same system. They increase, inter alia, the “light trapping” and passivize the back surface. Furthermore, the highly refractive layer acts as an ablation masking step in the subsequent process steps.

After the stack layer has been applied, ablation is performed, preferably by means of a UV laser, to expose the regions to be contacted, wherein preferably only the last deposited, high-silicon layer is ablated in the regions to be contacted, since only they absorb the UV radiation. The low-silicon layer is transparent for the UV radiation and therefore cannot be absorbed by it, so that ablation of it is prevented.

The remaining layer down to the silicon interface may then be etched away for subsequent contacting.

In this way the contact surfaces are opened locally without laser damage at the silicon interface.

A front surface texture is preferably created on the front surface of the solar cell before the doping of the emitter. This may be accomplished using wet chemical polishing and texture etching of the substrate on the front surface.

The wet chemical polishing may be performed as a first step, and where necessary on one side, this being followed by wet chemical texture etching on one side. The sequence may also be altered in that first wet chemical texture etching is performed for creating the front surface texture of the solar cell, and this is followed by single-sided wet chemical polishing of the back surface of the solar cell and deposition of a boron-containing precursor layer on the back surface of the solar cell.

A back surface contact solar cell made of crystalline silicon that is produced according to the method described in the foregoing has a wafer with an anti-reflection layer on the front surface, with an emitter and a base region (back surface field) on the back surface, as well as contacts on the back surface that were produced by laser ablation, wherein the pitch is at most 800 micrometers. The pitch is preferably significantly less, for example in the range of 100 micrometers or less, such as e.g. about 50 micrometers.

This yields high efficiency. In addition, dependence on the BSF portion f_{BSF} is reduced.

It is understood that the features of the invention cited in the foregoing and the features of the invention still to be explained in the following may be used not only in the specific combinations provided, but may also be used in other combinations or by themselves without departing from the context of the invention.

### BRIEF DESCRIPTION OF THE DRAWINGS

Additional features and advantages of the invention result from the following description of a preferred exemplary embodiment, with reference to the drawing.

FIG. 1 is a simplified section through an inventive solar cell;

FIG. 2 is a schematic depiction of the top view of a unit cell of the back surface of the solar cell according to FIG. 1;

FIG. 3a-f depicts the efficiency of a solar cell as a function of the BSF portion f_{BSF} and of the pitch p of the solar cell for different wafer qualities; and,

FIG. 4 is a schematic depiction of the connection of contacts by means of foil strips via welding points.

### DETAILED DESCRIPTION

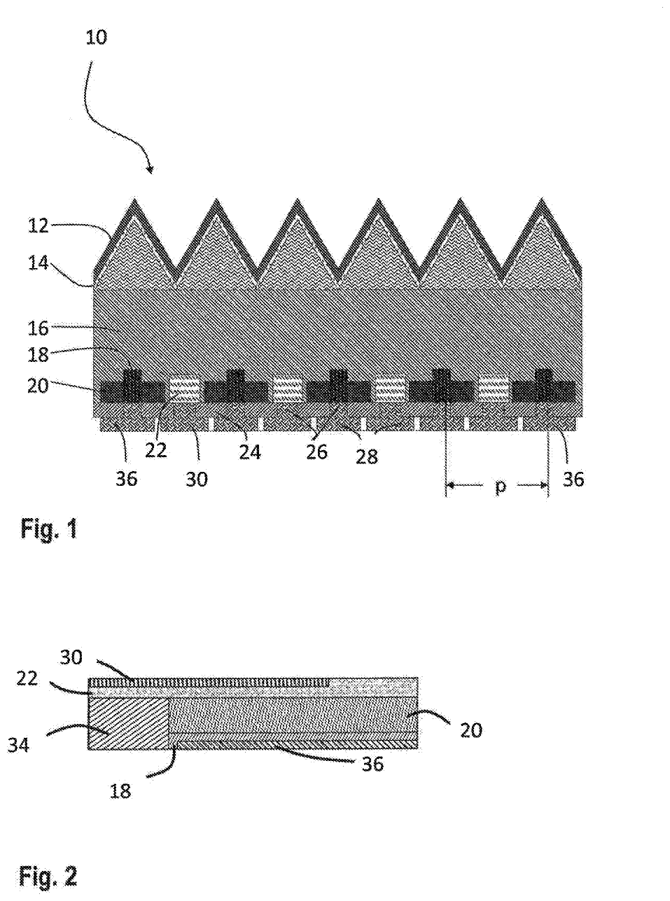

FIG. 1 schematically depicts the section of an inventive solar cell, which is identified overall with the number 10.

The solar cell 10 has an n-silicon wafer 16. The front surface of the latter is provided with a passivation and anti-reflection layer 12 on a pyramid-like texture. Thereunder is a front surface phosphorus diffusion layer, Front Surface Field (FSF) 14.

On its back surface the solar cell 10 has laser-doped boron emitter regions 20 on which are embodied emitters 18, each doped at selective strengths, to which contacts 28 are applied.

Furthermore, base regions 22, laser-doped by means of phosphorus, are disposed on the back surface of the solar cell 10. Using a passivation layer 24, the back surface is insulated from the contacts 28 through which the contacting to the selectively doped emitters 18 and the highly doped base regions 22 is produced.

FIG. 2 is a schematic depiction of the top view of a unit cell of the back surface of the solar cell 10 according to FIG. 1. The unit cell is continued in mirror image on the top and bottom of the drawing. The solar cell edge is to the left and to the right. 30 indicates the base contact region. 22 indicates the base region that was created by the BSF doping (Back Surface Field). 34 indicates the doping for the bus-bar. 20 indicates the emitter doping. 18 indicates the selectively more highly doped emitter. Finally, 36 indicates the emitter contact region.

The so-called “pitch” refers to the distance between two adjacent emitters 18 (the pitch is also in a sense the “period” of the solar cell). FIG. 1 indicates the pitch with p.

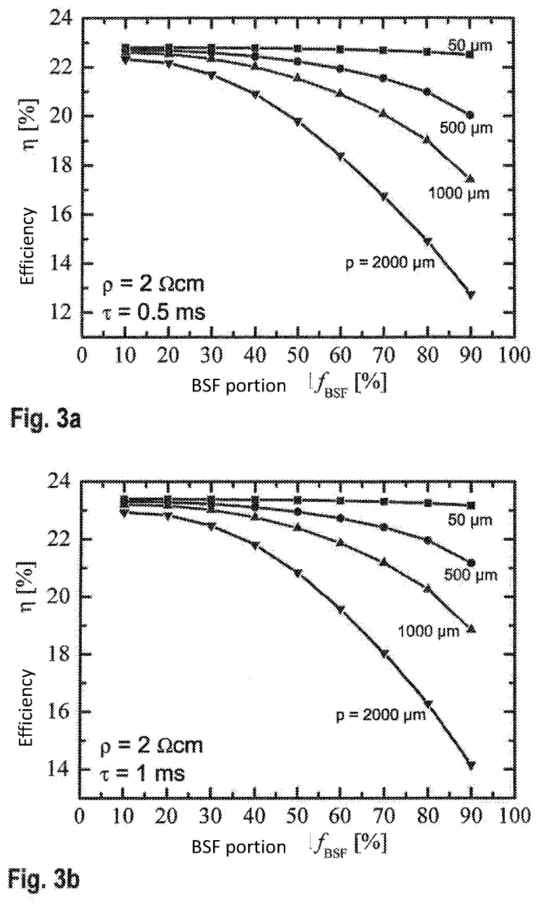

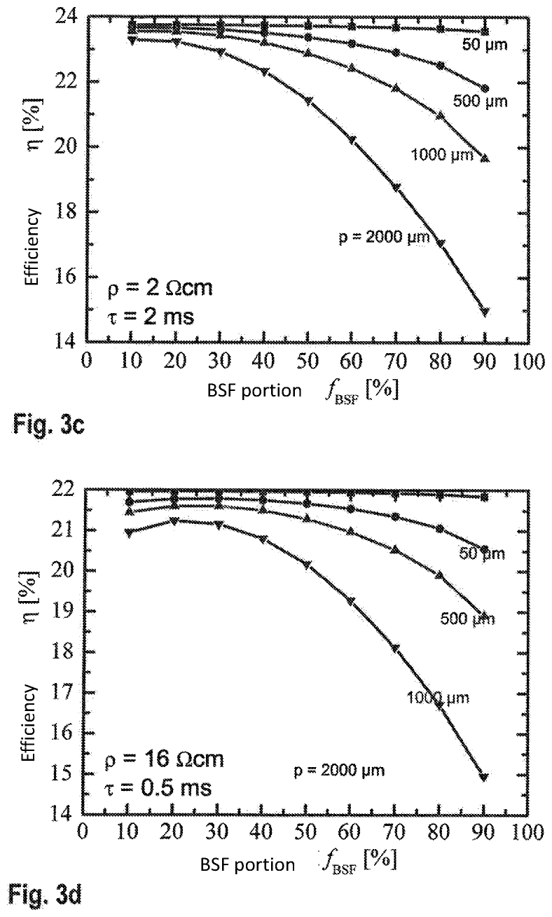

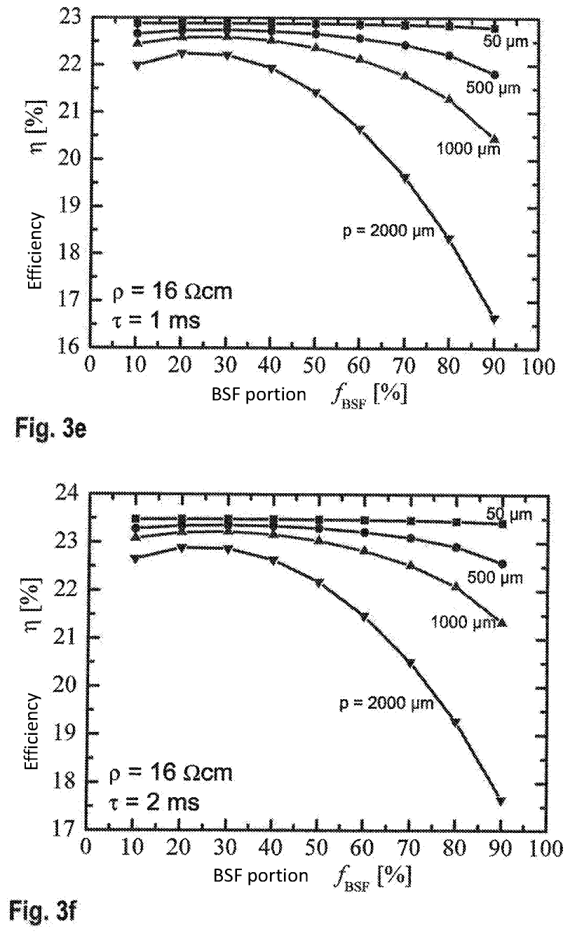

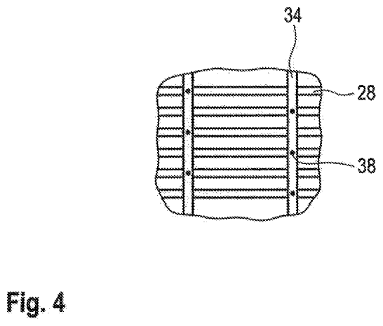

FIGS. 3a-f illustrate the relationship between the relative efficiency of a solar cell as a function of pitch p and of the BSF portion f_{BSF} (surface portion of the Ohmic contact (base region 22, BSF doping) to the total surface area (base region 22 plus emitter 18)), specifically for different wafers. Here ρ stands for the specific resistance of the waver and τ for the volume service life of the minority charge carrier.

This demonstrates that the smaller the pitch p, the greater the relative efficiency regardless of the specific resistance of the wafer and regardless of the volume service life. In addition, the smaller the pitch p, the lower the dependence on the BSF portion f_{BSF}. The pronounced maximums at a greater pitch p are smoothed with a smaller pitch p as a function of BSF portion f_{BSF}. At a pitch p of 50 micrometers, there is practically no more relationship to the BSF portion f_{BSF}.

According to the invention, this relationship to the pitch p is utilized to attain greatest possible efficiency.

According to the invention, using laser technology it is possible to produce a solar cell 10 having a pitch <800 micrometers, preferably <100 micrometers, more preferably <60 micrometers, in a manner that is relatively simple technically. As a rule, the pitch is greater than 5 micrometers.

The production of such a solar cell 10 shall be described in detail in the following.

The inventive method proceeds without any masking steps at all. Instead, laser doping steps and a laser ablation step to open the back surface passivation layer are used. The laser doping for producing the emitter may optionally also be replaced by a local ion implantation step. A further laser ablation step is used during the production of the contacts 28 for emitters 18 and base regions 22.

An n silicon wafer that is already base-doped is used for producing the solar cell 10.

First the front surface of the solar cell 10 undergoes wet chemical alkaline texturizing to produce a pyramid-like textured surface. Then the back surface of the solar cell 10 undergoes wet chemical polishing (alkaline or acid). This is followed by deposition of a boron, aluminum, or gallium-containing precursor layer on the back surface of the solar cell 10. The sequence of these steps may also be altered: Wet chemical polishing (where necessary on only one side) may be performed first, followed by single-side wet chemical texturing on the front surface of the solar cell 10.

The precursor layer on the back surface of the solar cell 10 may be applied, e.g., using a sputter system, or using a plasma-chemical deposition system (e.g. APCVD), or using a spin-coating method or a spray coating system.

Then a laser doping process is used to create a p emitter on the back surface of the solar cell 10. Here, a laser pulse melts the surface of the silicon wafer. Due to the high diffusion constants in liquid silicon, during the liquid phase the doping atoms present in the precursor layer diffuse into the surface of the silicon wafer within approx. 100 nanoseconds down to a depth of approx. 1000 nanometers and thus form the p emitter.

Here the laser beam may be formed, using an optical element, on the silicon surface such that a single laser pulse melts a sharply delimited rectangular region having the surface area X·Y. Preferably 0.02 millimeters<X<2 millimeters and 5 micrometers<Y<500 micrometers. Here the variable X defines the width of the emitter strips or points. The entire surface area of an emitter strip or point is doped due to repeated irradiation and movement of the silicon wafer, or due to the movement, by increment L in the Y direction, of the laser beam formed on the surface. Preferably 0.1·Y<L<Y here.

In addition, during the emitter doping a locally increased boron doping is produced below the emitter bus-bar region. This occurs either using beam forming during the laser irradiation or by using a different, independently focused laser beam. During the beam forming, it is critical that the pulse energy density is locally increased in the area of the contacts in order to obtain greater doping there. Corresponding beam forming may be attained, e.g. using a diffractive optical element.

Due to the locally increased boron doping below the emitter bus-bar region (also called selective emitter), a lower overall series resistance, and thus a better fill factor for the solar cell, is attained. Furthermore, the recombination of charge carriers on the metal semiconductor interface is reduced due to the locally increased boron doping below the emitter contact. Because of this, the open circuit voltage, and thus the efficiency of the solar cell 10, increases. Furthermore, the contact resistance is reduced, so that the total series resistance drops and the fill factor rises.

Both local dopings may be accomplished without an additional process step during the emitter laser doping. The doping profile, and thus the layer resistance, is adjusted by varying the laser pulse energy density.

After the laser doping of the emitter 18, the remaining precursor layer is removed in a wet chemical manner. The chemical solution used to this end depends on the precursor layer used.

Then the silicon wafer 16 is cleaned using a hydrochloric acid-hydrogen peroxide solution and then a hydrofluoric acid bath.

As an alternative to the laser doping described above using a previously deposited precursor layer, the emitter 18 of the solar cell 10 doped with boron may also be created using a local ion implantation step. Defect-free recrystallization of the silicon amorphized by the ion implantation and activation of the dopant atoms is attained using thermal oxidation, described below, which is also performed subsequently when there is a laser doping step.

Furthermore, a so-called back surface field (BSF) is created on the back surface of the silicon wafer in the form of a highly doped n region by laser doping using a phosphorus-rich precursor layer.

To this end, first a phosphorus-rich phosphorus-silicate glass layer is deposited on both the front surface and the back surface of the silicon wafer in a standard high-temperature tubular furnace. POCl₃ and O₂ are used for process gases. Deposition is performed at temperatures between 700° C. and 850° C. Furthermore, some of the phosphorus diffuses a few nanometers to 500 nanometers into the silicon wafer. The diffusion is optimized such that doping that is as low and superficial into the depth as possible occurs, but a phosphorus-rich phosphorus silicate glass is still created or a phosphorus-rich interface is present.

The phosphorus-rich interface or the phosphorus-silicate glass layer acts as dopant source for a subsequent laser doping process.

As described in the forgoing for the emitter doping, a laser pulse melts the surface of the silicon wafer. Due to the high diffusion constant in the liquid silicon, during the liquid phase phosphorus atoms present in the phosphorus-silicate glass layer diffuse within approximately 100 nanoseconds down to a depth of approx. 1000 nanometers into the surface of the silicon wafer and form the BSF region 32, a highly doped n region. As described in the foregoing, here the laser beam is formed on the silicon surface using an optical element such that a single laser pulse melts a sharply delimited rectangular region having a surface area X·Y in size. Again, the entire surface area of a BSF strip or point is gradually doped using a relative movement between silicon wafer and laser beam in the Y direction by the interval L. In addition, the same geometric relationships are used as already described above in relation to the emitter doping.

After the local BSF laser doping, the phosphorus-silicate glass layer is removed by means of hydrofluoric acid solution (1% to 50%).

Then some of the phosphorus-doped layer is etched back on at least the back surface of the substrate. To this end, a wet chemical solution made of hydrofluoric acid, nitric acid, acetic acid, and deionized water is used to etch back to a depth of approximately 10 nanometers to 300 nanometers of the phosphorus-doped layer. This etching step occurs as a function of the depth and phosphorus concentration on both sides of the silicon wafer or only on the back surface. The goal of the back etching is to reduce the phosphorus present in the boron emitter regions.

After the thermal oxidation, which will be described in the following, the phosphorus surface concentration in the emitter region should be at least five times less than the boron surface concentration. The reduction in the phosphorus concentration on the front surface is required if it is too highly phosphorus doped. The goal here is to obtain a phosphorus surface concentration of 1·10¹⁸ cm⁻³ to 1·10²⁰ cm⁻³ after the subsequent high temperature oxidation. In addition, the back-etching step provides chemical cleaning of the silicon wafer.

Then, first wet chemical cleaning is performed using a hydrochloric acid-hydrogen peroxide solution with a subsequent hydrofluoric acid bath.

This is followed by thermal oxidation as a so-called drive-in step. Here a silicon dioxide layer grows as surface passivation. Alternatively, a silicon nitride layer, a silicon oxynitride layer, or a silicon carbide stack layer may be used as well. During the drive-in, the dopant atoms diffuse further into the silicon wafer due to the high temperatures (approximately 800° C. to 1050° C.). Because of this, the surface concentration of the doping drops both in the back surface field (BSF) (base region) and in the front surface field (FSF), as well as in the emitter. The resulting silicon dioxide grows to a layer thickness of 5 nanometers to 105 nanometers, wherein layer thicknesses in the range of 5 nanometers to 20 nanometers are desired in combination with a further anti-reflection coating.

In order to reduce the effective reflection of the solar radiation on the surface of the solar cell 10, a silicon nitride layer is deposited on the front surface of the solar cell 10 by means of plasma-enhanced chemical vapor deposition (PECVD). The refractive index here should be between 1.9 and 2.3.

A 1 to 50 μm thick layer of aluminum is applied to the entire surface area of the back surface of the solar cell 10, e.g. by vaporization or cathode sputtering. This layer is used later to produce the contacts 28 on the base regions 22 and the emitters 18.

A metal, semi-conducting, or dielectric cover layer is applied to the aluminum layer, for example by vaporization, APCVD, PECVC, CVD, or cathode sputtering. This layer should be etch-resistant or should only able to be slightly etched by one of the etching agents subsequently used (for example, phosphoric acid, hydrochloric acid, sodium hydroxide, or potassium hydroxide). The layer may comprise, e.g. nickel, zinc, amorphous silicon or SiOx, silicon nitride, or silicon carbide.

Now the cover layer applied to the aluminum layer is ablated locally.

In a subsequent etching step, the aluminum in the regions exposed by means of the laser is removed by means of an etching agent (for example phosphoric acid, hydrochloric acid, sodium hydroxide, or potassium hydroxide) so that contacts 28 that are insulated from one another are created on the base regions 22 and the emitters 18.

Instead of creating insulation between the alternating contact regions by removing material by means of etching, according to one method variant insulation may be produced by selectively anodizing an aluminum layer.

To this end, after the application of the aluminum layer, a layer that is resistant to anodization is applied, for example SiOₓ, SiNₓ, SiCₓ, Si, Ni, Cu. This layer is selectively removed by means of laser ablation in the subsequent step. Then the ablated regions are completely anodized in an anodization bath (for example H₂SO₄ or oxalic acid) (in FIG. 1 the slits remaining between the adjacent contacts 28 would be completely filled in with aluminum oxide).

In any case, a very small pitch p is made possible with the use of the laser technology and may be on the order of magnitude of 100 μm or even in the range of about 50 μm. As may be seen from FIGS. 3a-f, this significantly improves efficiency η.

A pulsed laser system is used in the laser doping processes described in the foregoing, (see WO 2015/071217 A1 and DE 10 2004 036 220 A1, which are included in their entirety by reference here). The following laser parameters are preferred for producing an optimized depth profile of the dopant:
Pulse duration between 30 nanoseconds and 500 nanoseconds,
Wavelength between 500 nanometers and 600 manometers,
Pulse repetition rate between 1 kHz and 2 MHz,
Pulse energy density between 1 J/cm² and 5 J/cm².

As an option, the bus-bars (contact strips) 34 for further cell circuitry are created using laser welding of both contact polarities (emitter and base) with foil strips made of a metal foil. The foil strips may each overlap the other polarity. A dielectric layer or a layer stack insulates the foil strips from the complementary polarity.

In the simplest case, strips made of aluminum foil are used, the aluminum foil being provided with an insulating anodization layer on the side facing the contacts 28. The laser welding process occurs through the insulating layer for each polarity.

Of course, another dielectric layer or a layer stack may be used on the foil strips or on the back surface of the wafer for insulation.

What is claimed is:

1. A method for producing back surface contact solar cells from crystalline silicon, comprising the following steps:
(a) Doping, preferably by means of laser doping, for producing an n-doped or p-doped region;
(b) Exposing contact surfaces on the back surface of the solar cell, preferably by means of laser ablation;
(c) Applying a metal layer to a back surface of the solar cell; and,
(d) Structuring the metal layer by means of laser ablation for producing metal contacts, wherein the pitch is at most 800 micrometers,
characterized in that
in step (c) an aluminum layer is applied, then a layer which is resistant to anodization is applied, which in the subsequent step (d) is selectively ablated by means of laser and then is completely anodized in the ablated regions.

2. The method according to claim 1, in which method the doped region is produced using laser doping.

3. The method according to claim 1, in which method the pitch (p) is at most 500 micrometers.

4. The method according to claim 1, in which method the pitch (p) is at least 5 micrometers.

5. (canceled)

6. (canceled)

7. The method according to claim 1, in which method the metal contacts are connected using bus-bars that comprise strips of metal foil that are contacted by means of laser welding through at least one interposing dielectric layer.

8. The method according to claim 7, in which method strips made of anodized aluminum foil are used to produce the bus-bars.

9. The method according to claim 1, in which method a laser doping step is used for producing at least one of: a p-type emitter and an n back surface field (BSF) on the back surface of the solar cell.

10. The method according to claim 1, in which method a precursor layer that contains a dopant, in particular boron, aluminum, or gallium, is deposited on the back surface of the solar cell and a p-type emitter is created using local irradiation by means of a pulsed laser.

11. The method according to claim 1, in which method a p-type emitter is created locally using ion implantation with a dopant selected from the group of boron, aluminum, or gallium.

12. A back surface contact solar cell, comprising a wafer with an anti-reflection layer on the front surface, with an emitter region and a base region (back surface field) on the back surface, and having contacts on the back surface that were produced by laser ablation, wherein the pitch (p) is at most 800 micrometers.

13. The solar cell according to claim 12, in which solar cell the pitch (p) is at most 500 micrometers.

14. The solar cell according to claim 12, in which solar cell the contacts of base regions and emitter regions are connected using bus-bars made of metal foil strips that are electrically connected using laser welding points through a dielectric layer.

15. The solar cell according to claim 14, in which solar cell the metal foil strips comprise anodized aluminum foil.

16. The method according to claim 1 in which method the pitch (p) is at most 100 micrometers.

17. The method according to claim 1 in which method the pitch (p) is at most 60 micrometers.

18. The solar cell according to claim 12, in which solar cell the pitch (p) is at most 100 micrometers.

19. The solar cell according to claim 12, in which solar cell the pitch (p) is at most 60 micrometers.
